(19) United States
(12) Patent Application Publication
(10) Pub. No.: US 2026/0342345 A1
(43) Pub. Date: Oct. 29, 2026

(54) CONTROLLER FOR PROVIDING RINGING MITIGATION

(71) Applicants: Advanced Micro Devices, Inc., Santa Clara, CA (US); ATI Technologies ULC, Markham (CA)

(72) Inventors: Arash Moghimi, Markham (CA); Sriram Sundaram, Austin, TX (US); Ashish Jain, Austin, TX (US); DongMei Li, Shanghai (CN); Paulus Cornelis Maria Van Der Arend, Shanghai (CN)

(73) Assignees: Advanced Micro Devices, Inc., Santa Clara, CA (US); ATI Technologies ULC, Markham (CA)

(21) Appl. No.: 19/192,016

(22) Filed: Apr. 28, 2025

(51) Int. Cl. H03L 7/14; G06F 1/08; G06F 1/3206; H03L 7/083

(52) U.S. Cl. CPC H03L 7/14; G06F 1/08; G06F 1/3206; H03L 7/083

(57) ABSTRACT

The disclosed device provides ringing mitigation. The device, for example, is a working group processor including a local controller that measures the voltage level within the device and compares the voltage level to a threshold voltage level. If the controller determines that the voltage level is less than the threshold voltage level, the controller determines that a voltage-related event, such as a voltage droop, is occurring within the device. In response to detection of the voltage-related event, the controller selects and injects a stall pattern to stall workloads being processed by the device. The reduction in workloads reduces an activity counter, which thereby mitigates ringing within the device. Various other methods, systems, and computer-readable media are also disclosed.

### BACKGROUND

Demand for semiconductor devices that provide high-processing capability, while also providing optimal uptime, stability, and consistency has increased. Various systems, devices, and components of semiconductor devices can be utilized to optimize the foregoing desired capabilities. For example, digital frequency locked loop provides a clock management mechanism in the device that controls the clock signaling in the semiconductor device to ensure accurate timing and synchronization of workloads and operations executed and conducted by the semiconductor device. Additionally, power delivery networks are utilized in semiconductor devices and integrated circuits to supply controlled and efficient electrical power to the various components of the semiconductor device. Furthermore, capacitive activity counters can be utilized in semiconductor devices to measure the activity occurring in the semiconductor device and can facilitate power management systems of the semiconductor devices to adjust clock signal speeds, enter various power states, and adjust various performance parameters. In certain scenarios, ringing (e.g., undesirable oscillations or fluctuations in voltage or current) can occur. For example, ringing can occur in the semiconductor device when a positive feedback loop is entered by a power delivery network, a digital frequency locked loop, a clock distribution tree, and the capacitive activity counter of the semiconductor device. Various techniques can be utilized to reduce or mitigate ringing that can affect a semiconductor device.

### BRIEF DESCRIPTION OF THE DRAWINGS

The accompanying drawings illustrate a number of exemplary implementations and are a part of the specification. Together with the following description, these drawings demonstrate and explain various principles of the present disclosure.

FIG. 1 is a schematic diagram of an exemplary system including a computing device providing ringing mitigation according to implementations of the present disclosure.

FIG. 2 is a schematic diagram of working group processors for use with a system for providing ringing mitigation according to implementations of the present disclosure.

FIG. 3 is a schematic diagram of various components of a working group processor that can be utilized to provide ringing mitigation according to implementations of the present disclosure.

FIG. 4 is a schematic diagram of interactivity and a feedback loop occurring among a power delivery network, a digital frequency locked loop, a clock distribution tree, and an activity counter according to implementations of the present disclosure.

FIG. 5 is a schematic diagram providing graphs illustrating performance of the system according to implementations of the present disclosure in providing ringing mitigation versus performance of traditional techniques.

FIG. 6 is a flow diagram of an exemplary method for providing ringing mitigation according to implementations of the present disclosure.

Throughout the drawings, identical reference characters and descriptions indicate similar, but not necessarily identical, elements. While the exemplary implementations described herein are susceptible to various modifications and alternative forms, specific implementations have been shown by way of example in the drawings and will be described in detail herein. However, the exemplary implementations described herein are not intended to be limited to the particular forms disclosed. Rather, the present disclosure covers all modifications, equivalents, and alternatives falling within the scope of the appended claims.

### DETAILED DESCRIPTION

The present disclosure is generally directed to providing ringing mitigation for processors and/or other computing devices. As the use of computing devices to perform various types of operations continues to increase, the performance, stability, reliability, and health of the computing devices is of ever-increasing concern. Additionally, the effective use of resources, such as power, voltage, and current are also of concern.

Interactions in a computing system between a computing device's power delivery network, digital frequency locked loop, clock distribution tree, and capacitive activity counter can result in positive feedback loops that can cause the computing system or device to operate in an unstable oscillatory region. In such a scenario, the computing system can run a workload that triggers a voltage-associated event (e.g., voltage droop event) due to DiDt (i.e., change in current (i) over time (t)), and there can be frequency drops due to the resulting voltage decrease. The voltage decrease can then cause the capacitive activity counter to decrease in response to a decrease in frequency, and then the voltage can increase due to the reduced capacitive activity counter. As the voltage is increasing, the capacitive activity counter increases, which thereby causes another voltage-associated event. The system can then repeat the foregoing cycle causing a positive feedback loop that causes ringing (i.e., unstable oscillatory patterns) in the computing device.

Existing techniques for mitigating such ringing involve reducing the steepness of the stretch response, which also reduces the DiDt mitigation of the computing device. This involves reducing the gain introduced by the frequency portion of the positive feedback loop, however, doing so reduces protection against DiDt events, such as voltage droop. The foregoing can cause the computing system to operate at a lower frequency for the same voltage level when compared to the implementation of the present disclosure. Other existing techniques involve selecting steeper digital frequency locked loop stretch responses and/or implementing changes to power delivery network settings as methods for mitigating droop events. The steeper stretch response can aggravate ringing and/or increase the gain of the positive feedback loop and, as a result, it is common for the computing system to operate in an unstable region and encounter failures due to the ringing that occurs. Still further techniques involve reducing the amount of voltage droop that occurs due to changes in the capacitive activity counter.

Some implementations of the present disclosure, on the other hand, not only mitigates ringing issue, but also simultaneously enhances DiDt protection. Some implementations of the present disclosure can include disrupting an activity counter (e.g., capacitive activity counter) portion of the feedback loop that causes the ringing using a specialized controller within a working group processor of the computing device to inject stall patterns when the detected voltage level is below a threshold value indicative of a voltage droop event. For example, the controller and/or other components of some implementations of the present disclosure can sense localized voltage droop events (or other events) within a local working group processor and can utilize a controller within the local working group processor to trigger a stall/throttle pattern when the voltage value measured by a power supply monitor drops below a threshold value. In some such implementations, when a DiDt event (e.g., voltage droop) is detected inside the working group processor, the controller can initiate, execute, and/or provide a throttle/stall pattern to stall the workloads (e.g., graphics workloads) that are executing in the local working group processor. In certain implementations, different stall/throttle patterns can be utilized with different types of events and/or severity of events. The stall pattern can cause one, some, or all operations to be stopped in the working group processor, and the reduction in processing activity will reduce the activity counter, which in turn will mitigate voltage droop events, thereby causing the voltage measurements measured by the power supply monitor to increase. In some implementations, when a DiDt event has completed (indicated by the increase in voltage value to at least the threshold), a controller can gradually release the stall/throttle pattern from a current level until the throttle/stall is completely released. This can avoid causing new DiDt issues that could result from abruptly increasing the activity counter. Based on at least the foregoing and the present disclosure, some implementations of the present disclosure can break the positive feedback loop with a reduction in activity counter change instead of a reduction in frequency change. The foregoing occurs because the controller can maintain the same clock frequency, but can inject a throttle/stall pattern to prevent voltage droop events from occurring, which allows for mitigation of ringing while maintaining DiDt protection with a steeper stretch response.

Some implementations of the present disclosure can provide enhancements in graphics processing maximum frequency due to the ability to detect and mitigate local voltage droop events within a working group processor. Some implementations of the present disclosure can mitigate ringing without shallowing the digital frequency locked loop stretch response. Still further, some implementations of the present disclosure can provide a cost-efficient approach when compared to other techniques.

In certain implementations, a system for providing ringing mitigation is provided. The system can include a plurality of working group processors. In certain implementations, a first working group processor of the plurality of working group processors can include a controller configured to perform a variety of operations. In certain implementations, for example, the first working group processor can detect that a voltage-related event is occurring in the first working group processor based on a voltage level associated with the first working group processor being less than a threshold voltage level. In certain implementations, the controller can maintain a clock frequency for the first working group processor, such as to ensure that protection against further DiDt and/or other events is maintained. In certain implementations, the controller can inject, in response to the voltage-related event occurring and while the clock frequency is maintained, a stall pattern locally in the first working group processor to stall a workload of the first working group processor. In certain implementations, the controller can mitigate, within the first working group processor, ringing by reducing an activity counter based on the stall pattern stalling the workload of the first working group processor.

In certain implementations, the controller can determine when the voltage-related event is no longer occurring. In certain implementations, the controller can gradually release the stall pattern from a current level until the stall pattern is released. In certain implementations, the controller can select the stall pattern from a plurality of stall patterns. In certain implementations, each stall pattern of the plurality of stall patterns can stall a different amount of clock cycles associated with stalling the workload. In certain implementations, the controller can set the threshold voltage level as a preset static threshold voltage level. In certain implementations, the controller can set the threshold voltage level as a dynamic threshold voltage level, wherein the dynamic voltage threshold level comprises a threshold value relative to a moving average of voltage values measured for the first working group processor over a period of time.

In certain implementations, the controller can monitor, by utilizing a power supply monitor, the voltage level associated with the first working group processor. In certain implementations, the controller can mitigate the ringing by breaking a feedback loop occurring among a power delivery network, a digital frequency locked loop, a clock distribution tree, and the activity counter. In certain implementations, the controller maintain protection against the voltage-related event, one or more future voltage-related events, a DiDt event, or a combination thereof, such as by maintaining the clock frequency for the first working group processor. In certain implementations, the voltage-related event can include a voltage droop event occurring within the first working group processor. In certain implementations, the controller can detect a feedback loop occurring among a power delivery network, a digital frequency locked loop, a clock distribution tree, and the activity counter of the first working group processor. In certain implementations, the controller can maintain a stretch response slope provided by a digital frequency locked loop to maintain the clock frequency.

In certain implementations the system can further include a second working group processor of the plurality of working group processors, and the second working group processor can include a controller configured to perform a variety of operations. In certain implementations, for example, the controller can compare a voltage level associated with the second working group processor to the threshold voltage level. In certain implementations, the controller can detect that a different voltage-related event is occurring based on the voltage level associated with the second working group processor being less than the threshold voltage level. In certain implementations, the controller of the second working group processor can maintain a clock frequency for the second working group processor, and inject, in response to the different voltage-related event occurring and while the clock frequency for the second working group processor is maintained, a different stall pattern locally in the second working group processor to stall a different workload of the second working group processor. In certain implementations, the controller can mitigate, within the second working group processor, ringing by reducing a different activity counter based on the stall pattern stalling the different workload of the second working group processor.

In certain implementations, a device, such as a working group processor, can provide ringing mitigation. In certain implementations, the device can include a controller that can perform a variety of operations. In certain implementations, for example, the controller can monitor, such as by utilizing a power supply monitor, a voltage level associated with the device. In certain implementations, the controller can compare the voltage level associated with the device to a threshold voltage level. In certain implementations, the controller can detect that a voltage-related event is occurring in the device based on the voltage level being less than the threshold voltage level. In certain implementations, the controller can provide, in response to the voltage-related event occurring and while maintaining a clock frequency for the device, a stall pattern locally in the device to stall a workload of the device. In certain implementations, the controller can mitigate, within the device, ringing by reducing an activity counter based on the stall pattern stalling the workload of the device.

In certain implementations, the controller can mitigate the ringing by breaking a feedback loop occurring among a power delivery network, a digital frequency locked loop, a clock distribution tree, and the activity counter of the device. In certain implementations, the controller can determine, after the activity counter has reduced, that the voltage-related event is over based on the voltage level increasing to the threshold voltage level. In certain implementations, the controller can release, in response to the voltage-related event being over, the stall pattern from a current level until the stall pattern is released. In certain implementations, the controller can select the stall pattern from a plurality of stall patterns in accordance with a type of the voltage-related event, a severity of the voltage-related event, or a combination thereof.

In certain implementations, a method for providing ringing mitigation in a semiconductor device is provided. In certain implementations, the method can include measuring, by utilizing a power supply monitor of a device, a voltage level associated with the device. In certain implementations, the method can include comparing, by utilizing a controller of the device, the voltage level associated with the device to a threshold voltage level. In certain implementations, the method can include determining that a voltage-related event is occurring in the device based on the voltage level being less than the threshold voltage level. In certain implementations, the method can include providing, in response to the voltage-related event occurring and while maintaining a clock frequency for the device, a stall pattern locally in the device to stall a workload of the device. In certain implementations, the method can include reducing an activity counter based on the stall pattern stalling the workload of the device to mitigate ringing within the device. In certain implementations, the method can include gradually releasing the stall pattern after the voltage-related event ends and the voltage level satisfies the threshold voltage level.

As will be explained in greater detail below, implementations of the present disclosure can provide ringing mitigation by utilizing a controller of a working group processor (or other device) of a semiconductor device. In certain implementations, for example, the system and methods provide a power supply monitor-based DiDt controller that senses localized power supply monitor voltage droop events and triggers local throttling at the working group processor when the voltage value drops below a threshold voltage value. In certain implementations, for each working group processor in a semiconductor device, a controller instance and/or device can be incorporated. The controller can be utilized for working group processor-level local voltage droop controlling. When a DiDt event (e.g., a voltage droop event) is detected inside a working group processor (e.g., based on the voltage level measured by the power supply monitor being below a threshold voltage value), the controller can trigger propagation of a throttle pattern to stall the workloads (e.g., graphics workloads and/or other types of workloads) that are running or executing in the working group processor, while also maintaining the clock frequency within the working group processor. The stall pattern can cause a reduction in activity in the working group processor, which will reduce the activity counter, which will in turn mitigate voltage-related events (e.g., voltage droop events), thereby causing the voltage level measurement to increase. When the DiDt event is determined to be over, such as indicated by an increase in the voltage level such that the voltage level satisfies a threshold voltage level set for the working group processor, the controller logic can gradually release the throttle pattern from its current level until it is completely released. By doing so, this will avoid causing new DiDt issues that could occur based on abruptly increasing the activity counter. By effectively providing ringing mitigation by reducing the activity counter via the stall pattern, the system and methods enable operation at a higher frequency for the same voltage level, provide enhanced working group processor performance, achieve mitigation at a lower cost, enable adjustments to be dynamically on silicon, and provide a variety of other benefits as discussed in the present disclosure.

Features from any of the implementations described herein can be used in combination with one another in accordance with the general principles described herein. These and other implementations, features, and advantages will be more fully understood upon reading the following detailed description in conjunction with the accompanying drawings and claims.

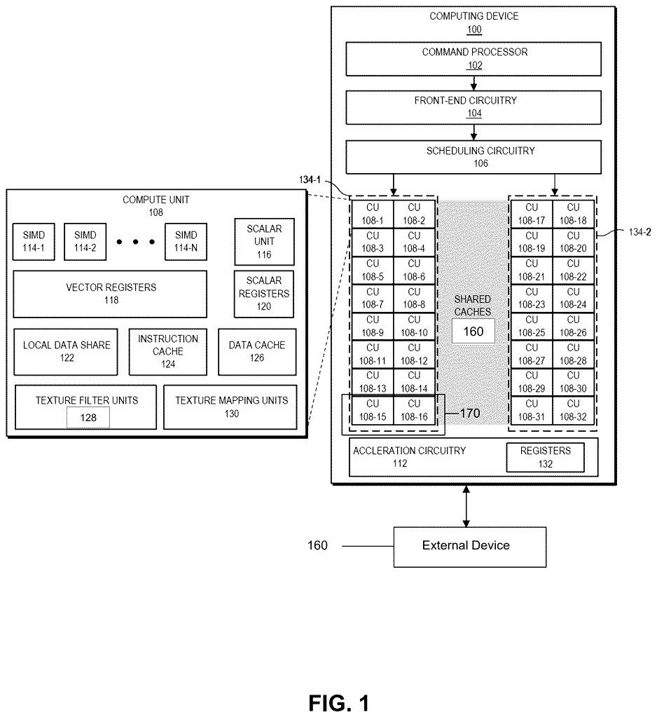

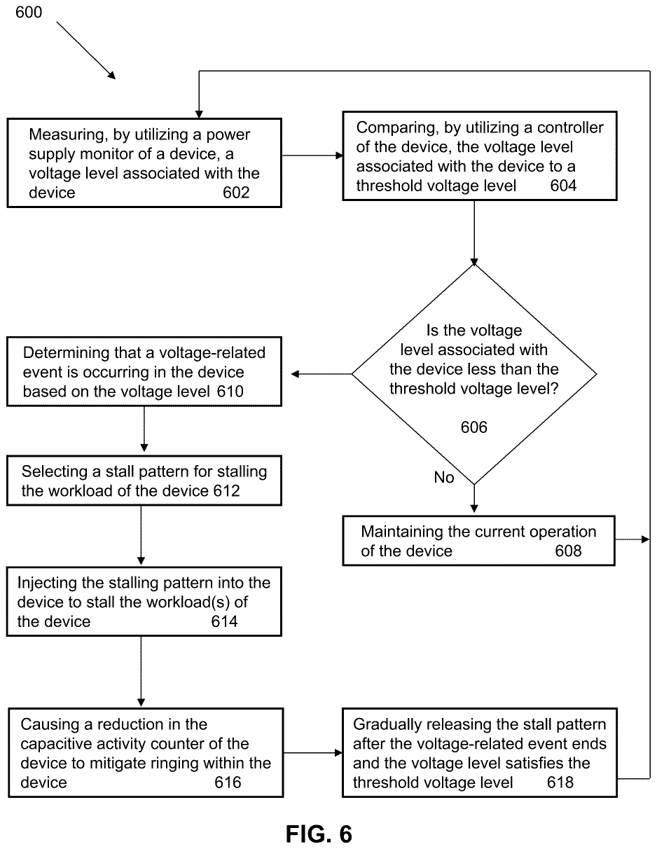

The following will provide, with reference to FIGS. 1-6, detailed descriptions of providing ringing mitigation, such as for a semiconductor device including one or more processors. Detailed descriptions of example systems will be provided in connection with FIGS. 1, 2, 3, 4, and 5. Detailed descriptions of corresponding methods will also be provided in connection with FIG. 6. Any of the components, functionality, features, and/or other aspects of the systems and methods of FIGS. 1, 2, 3, 4, 5, and 6 can be combined together to form various implementations of the present disclosure.

FIG. 1 is a schematic block diagram of an exemplary computing device 100 providing ringing mitigation according to implementations of the present disclosure. In certain implementations, the system 100 can correspond to any number of devices, communication links, programs, components, printed circuit boards, and/or any other systems and devices. In certain implementations, the computing device 100 can include any combination of devices, communication links, programs, components, printed circuit boards, and/or any other combinations of systems and devices. In certain implementations, the computing device 100 can be incorporated within a computing system including any number of devices, communication links, programs, or a combination thereof. Computing device 100 can correspond to a computing device, such as a desktop computer, a laptop computer, a server, rack-mounted computer, device that forms a part of a distributed compute cluster (such as within a data center), a tablet device, a mobile device, a smartphone, a wearable device, an augmented reality device, a virtual reality device, a network device, an electronic device, television, gaming console, and/or other device. In certain implementations, the computing device 100 can include any number of processors, memories, communication devices, printed circuit boards, and/or other components. The computing device 100 can be configured to perform operations, such as, but not limited to, obtain data, process data, store data, transmit data, modify data, perform any action with respect to data, or a combination thereof.

In certain implementations, the computing device 100 can be configured to incorporate any of the components providing the operative functionality described in the present disclosure. In certain implementations, the computing device 100 can include a command processor 102, front-end circuitry 104, scheduling circuitry 106, any number of compute units 108, 108-1, 108-2, 108-3, 108-4, 108-5,108-6, 108-7, 108-8, 108-9, 108-10, 108-11, 108-12, 108-13, 108-14, 108-15, 108-16, 108-17, 108-18, 108-19, 108-20, 108-21, 108-22, 108-23, 108-24, 108-25, 108-26, 108-27, 108-28, 108-29, 108-30, 108-31, 108-32, shared caches 160, acceleration circuitry 112, registers 132, and/or external devices 160. In certain implementations, the command processor 102 can be and/or can include a microprocessor, microcontroller, operating system, and/or other hardware device capable of analyzing and/or executing commands and instructions. In certain implementations, the command processor 102 can manage and/or facilitate the flow of operations to be conducted by the command processor 102 and/or components of computing device 100 in response to commands (e.g., from external device 160 and/or other components of computing device 100). In certain implementations, the front-end circuitry 104 can be configured to perform initial processing and management of data and/or commands as they enter the computing device 100, and can manage communication between the components of the computing device 100 and/or external devices 160.

In certain implementations, the scheduling circuitry 106 can be utilized to manage and control the order of execution of operations and/or tasks for the computing device 100. In certain implementations, the scheduling circuitry 106 can allocate computing resources (e.g., processing power, memory, compute units, etc.) based on the type of operation, tasks, and/or activity to be performed by the computing device 100. In certain implementations, each compute unit 108, 108-1, 108-2, 108-3, 108-4, 108-5,108-6, 108-7, 108-8, 108-9, 108-10, 108-11, 108-12, 108-13, 108-14, 108-15, 108-16, 108-17, 108-18, 108-19, 108-20, 108-21, 108-22, 108-23, 108-24, 108-25, 108-26, 108-27, 108-28, 108-29, 108-30, 108-31, 108-32 can incorporate single instructions multiple data parallel computing components 114-1-114-N, scalar unit 116, vector registers 118, scalar registers 120, local data shares 122, instruction cache 124, data cache 126, texture filter units 128, and texture mapping units 130. In certain implementations, the acceleration circuitry 112 can be utilized to enhance the performance of specific tasks and operations to be conducted by the computing device 100. In certain implementations, the acceleration circuitry 112 can include graphics processing units, digital signal processors, field-programmable gate arrays, application specific integrated circuits, neural processing units, any other type of acceleration circuitry, or a combination thereof. In certain implementations, the registers 132 can be utilized to store data, such as during performance of an operation by the computing device 100. Notably, the computing device 100 can incorporate any of the components and/or functionality as described in the present disclosure and/or FIGS. 1-6.

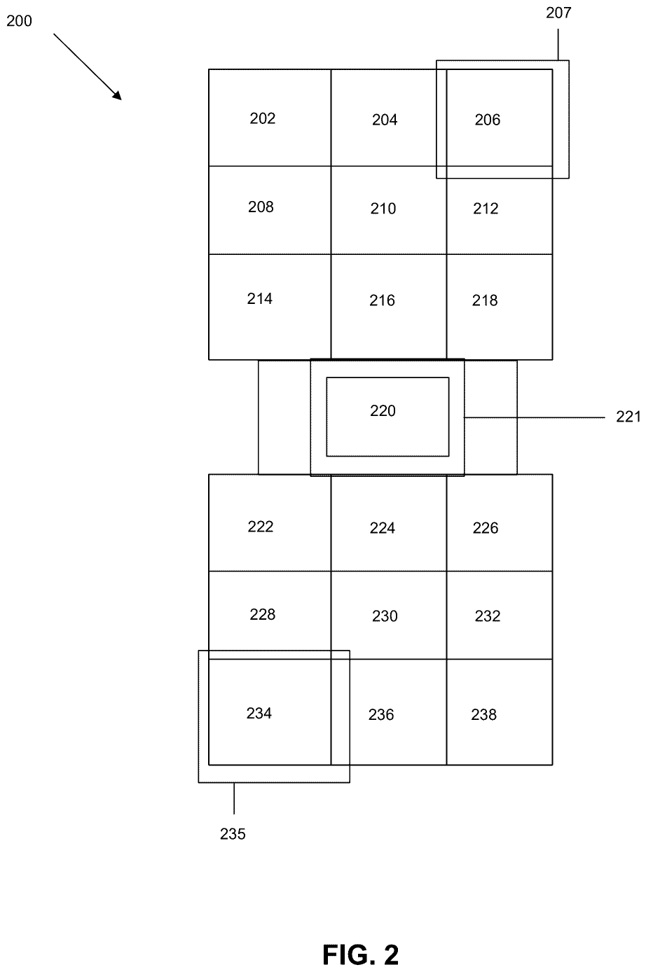

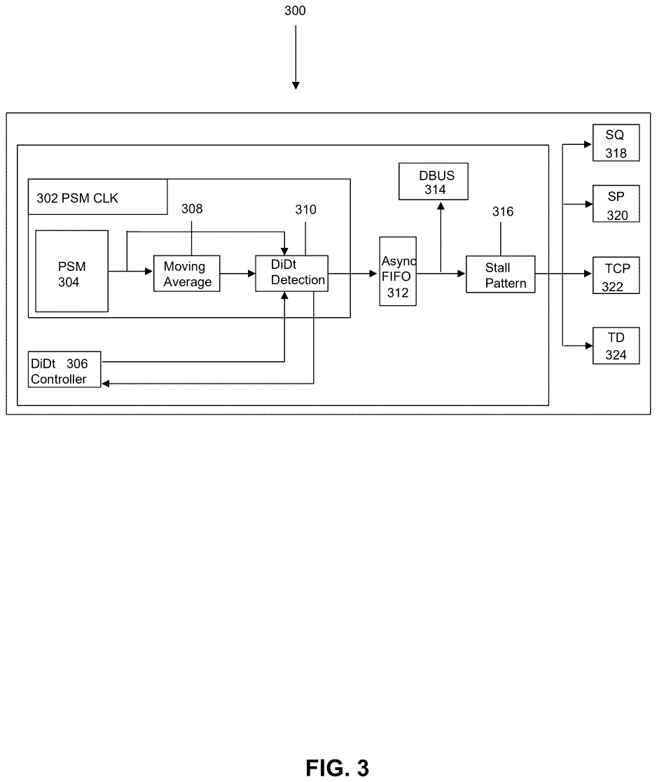

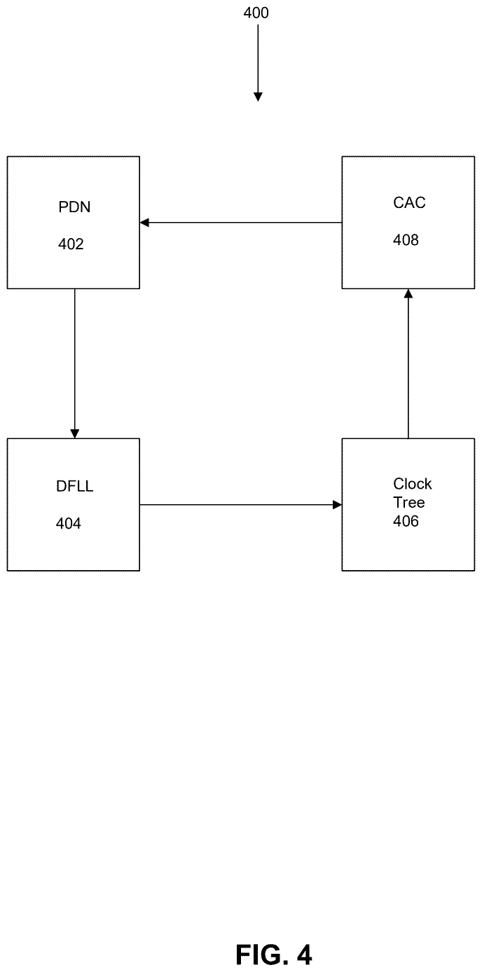

Referring now also to FIG. 2, a schematic diagram of a portion of a computing device 200 of a group working group processors 202, 204, 206, 208, 210, 212, 214, 216, 218, 220, 222, 224, 226, 228, 230, 232, 234, 236, and 238 for use with a system for providing ringing mitigation according to implementations of the present disclosure is shown. In certain implementations, the components of FIG. 2 can be utilized with and/or reside within the computing device 100, and/or any of the other systems, components, and/or devices shown in FIGS. 1-4. In certain implementations, in addition to being incorporated into the computing device 100 shown in FIG. 1., the computing device 200 can also include any of the components illustrated in FIG. 3 and FIG. 4. For example, in FIG. 3, working group processor 300 includes a plurality of components, which can be included in any of the working group processors of FIG. 3. As another example, the computing device 200 can include a digital frequency locked loop 404, a clock distribution tree 406, and an activity counter (e.g., capacitive activity counter) 408, as shown in FIG. 4.

As shown in FIG. 2, any number of working group processors 202, 204, 206, 208, 210, 212, 214, 216, 218, 220, 222, 224, 226, 228, 230, 232, 234, 236, and 238 can be utilized with computing device 200. Illustratively, FIG. 2 illustrates the spatial variation of potential voltage droop or other voltage-related events that can occur within a computing device 200. For example, in a graphics processor implementation utilizing the components of FIG. 2, voltage droop can be higher at the periphery as indicated by the box 207 over working group processor 206 and the box 235 over working group processor 234 when compared to the working group processor 220 covered by box 221 (e.g., 60-70 mV which can be worth 150-200 MHz GFXCLK frequency), which is near the central region of the computing device 200. Based on the disparity in droop severity/level at the periphery versus the center, the implementations of the present disclosure provide for local voltage droop detection within each individual working group processor 202, 204, 206, 208, 210, 212, 214, 216, 218, 220, 222, 224, 226, 228, 230, 232, 234, 236, and 238 of the computing device 200 to enable faster response times, while also reducing ringing and providing enhanced voltage event mitigation capabilities.

Referring now also to FIG. 3, a schematic diagram of various components of a working group processor 300 (or other type of processor or device) that can be utilized to provide ringing mitigation according to implementations of the present disclosure is shown. In certain embodiments, the working group processor 300 can be one of many working group processors 300 of a computing device. In certain implementations, the working group processor 300 can be a combination of compute units, such as two or more compute units. In certain implementations, the working group processor 300 can include any type or number of components utilized on a working group processor or work group processor. In certain implementations, the working group processor 300 can include a power supply monitor (PSM) clock 302, a power supply monitor (PSM) 304, a controller 306 (e.g., a DiDt controller), a moving average calculation component 308, a detection component 310 (e.g., a DiDt detection component), an asynchronous FIFO component 312, a data bus 314, a stall pattern component 316, a plurality of types of stall patterns for sequencer (SQ) 318, shader processor (SP) 320, texture cache pipe (TCP) 322, texture data path (TD) 324, among others.

In certain implementations, the PSM clock 302 can be a clock that can be dynamically scaled based on the power requirements or needs of the working group processor 300 and/or other components. In certain implementations, the PSM clock 302 can be a clock that operates at a reduced frequency based on power requirements or needs as well. In certain implementations, the PSM clock 302 can be utilized in conjunction with dynamic voltage and frequency scaling to enable adjustment of both voltage and clock frequency to optimize power consumption and performance of the processor. In certain implementations, the PSM clock 302 can be utilized in voltage-related event detection, such as voltage droop detection. In the PSM clock 302 domain, droop detection can be facilitated by monitoring and detecting voltage drops within the specific power domain that supplies power to the PSM clock 302. In certain implementations, the PSM clock 302 can provide a clock or timing signal that drives or synchronizes the monitoring of power supply conditions, such as, but not limited to, voltage and/or current levels within the working group processor 300.

In certain implementations, the PSM 304 can be a component of the working group processor 300 that is configured to monitor the power supply to the working group processor 300 and/or other system components. In certain implementations, the PSM 304 can ensure that the power delivered is within the required specifications (e.g., voltage, current, etc.), and can also be utilized to facilitate detection of voltage droops, voltage spikes, and/or other voltage-related events. In certain implementations, the PSM 304 can monitor the health of the power supply of the processor and the voltages provided to the working group processor 300, memories, and/or accessories. In certain implementations, the PSM 304 can also monitor the current drawn by the working group processor 300 and/or other components. In certain implementations, the PSM 304 can be configured to generate alerts or initiate actions in response to detection of a voltage droop event, volage-related event, and/or other monitored condition.

In certain implementations, the controller 306 (e.g., DiDt controller) can be utilized to manage, coordinate, and/or control the operative functionality and/or components of the working group processor 300. In certain implementations, each working group processor 300 can include a single controller 306 instance, however, in certain implementations, any number of controller 306 instances can be utilized. In certain implementations, the controller 306 can comprise software, hardware, or a combination thereof. In certain implementations, the controller 306 can generate control signals for controlling the various components of the working group processor 300. In certain implementations, the controller 306 can be utilized to inject a stall pattern to stall execution of operations by the working group processor 300, such as when the voltage value (or other measurable value, such as current, etc.) as measured by the PSM 304 is below a threshold voltage value (or other measurable value), thereby indicating a voltage-associated event (e.g., voltage droop) or other event of interest. In certain implementations, the controller 306 can be utilized to execute, initiate, or inject a specific type of stall pattern (or throttle pattern) based on the severity of the voltage-related event detected within the working group processor 300. For example, certain stall patterns can be utilized based on the severity of the voltage-associated event (e.g., threshold level of voltage droop). In certain scenarios, a more aggressive stall pattern (e.g., 14 or 15 out of 15 graphics clock cycles are to be stalled using the stall pattern) can be utilized, such as if the voltage-associated event has a threshold level of severity. In certain scenarios, a less aggressive stall pattern (e.g., 2 out 15 clock cycles are to be stalled using the stall pattern) can be injected by the controller 306 into to working group processor 300 (e.g., via a signal) if the voltage-associated event is less severe, such as if the voltage droop is less than a threshold voltage value.

In certain implementations, once the stall pattern is executed, the activity (e.g., execution and/or performance of operations) in the working group processor 300 will reduce. The reduction in activity can reduce the activity counter (e.g., capacitive activity counter) (discussed in further detail in the description accompanying FIG. 4), which in turn will mitigate voltage-associated events (e.g., droop events), which will then cause the voltage/PSM measurement readings to increase. In certain implementations, the controller 306 can, such as when the voltage-associated event is over or is nearly completed, gradually release the stall pattern that was injected and/or provided to the working group processor 300 by the controller 306. In certain implementations, the controller 306 can gradually release the stall pattern from a current level until the stalling is completely released (i.e., no stalling effect is on the working group processor 300 operations). In certain implementations, the voltage-associated event can be determined to be over when the voltage value as measured by the PSM 304 or other components satisfies (e.g., equals or exceeds) the voltage threshold value set for the working group processor 300.

In certain implementations, the moving average calculation component 308 can be a component that calculates a moving average of voltage values (or other types of measurable values) measured by the PSM 304. In certain implementations, the controller 306 can trigger the stall pattern (or throttling) when the measured PSM voltage value falls below a threshold relative to the moving average calculated by the moving average calculating component 308. In certain embodiments, the moving average calculation component can be software, hardware, or a combination thereof.

In certain implementations, the detection component 310 (e.g., a DiDt detection component) can be utilized to determine when a DiDt event, such as a voltage-associated event (e.g., voltage droop), current-associated event, and/or other event affecting the working group processor 300. In certain implementations, the basis by which a DiDt event is detected can be a static threshold (e.g., a static PSM voltage threshold). For example, the detection component 310 can be configured to detect the presence of a DiDt event if the measured PSM voltage value is less than the static threshold and the DiDt event may not be present if the PSM voltage is the same or exceeds the static threshold. In certain implementations, instead of using a static threshold, the detection component 310 can utilize a dynamic threshold. In such implementations, the detection component 310 can utilize a moving average of the PSM values and the controller 306 can trigger the stall pattern and/or throttling when the PSM value at a given point in time falls below a threshold relative to the calculated moving average. In certain implementations, this can allow the controller 306 to trigger the stall pattern/throttling when there is an abrupt change in PSM values.

In certain implementations, the asynchronous FIFO component 312 can be a component that receives the detections conducted by the detection component 310. In certain implementations, the asynchronous FIFO component 312 can be utilized for data storage and transfer, and can be utilized to handle data that is read and written at varying clock rates or timings. For example, the asynchronous FIFO component 312 can be utilized to handle data and operations controlled by clocks in the PSM domain and the working group processor domain. In certain implementations, the data bus 314 can be a communication pathway utilized to transfer data and/or signals between different components of the working group processor 300. In certain implementations, the stall pattern component 316 can be utilized to store stall patterns and/or throttle patterns, which can be utilized to stall operations conducted by the working group processor 300. In certain implementations, the stall patterns can be updated, replaced, removed, or added to. In certain implementations, any types of stall patterns that target specific types of operations conducted by the working group processor 300, specific clock cycles, types of components of the working group processor 300, portions of operations conducted by the working group processor 300, specific durations of time for stalling operations, specific sizes of operations, operations that utilized a threshold amount of computer resources (e.g., memory, processor resources, etc.), any other types of stall patterns, or a combination thereof. In certain implementations, the stall patterns can be utilized for sequencer (SQ) 318, shader processor (SP) 320, texture cache pipe (TCP) 322, texture data path (TD) 324, and/or other types of operations and/or activities and/or components that can be stalled.

Referring now also to FIG. 4, a schematic diagram 400 of interactivity among components of a semiconductor device (e.g., working group processor, processor cores, etc.) and a feedback loop occurring among the components according to implementations of the present disclosure is shown. In certain implementations, each of the components of schematic diagram 400 can be included within a working group processor, a computing device including one or more working group processors, or a combination thereof. In certain implementations, the components can include a power delivery network 402, a digital frequency locked loop 404, a clock distribution tree 406, and an activity counter (e.g., capacitive activity counter) 408. In certain implementations, the power delivery network 402 can include components that are responsible for delivering and distributing power to the various components of the semiconductor device. For example, the power delivery network 402 power rails that provide the pathways for distribution of power to the various components of the working group processor, inductors and filters to facilitate reduction and/or smoothing of noise in the power signals propagated by the power deliver network 402, voltage regulators for converting input power to the necessary voltage levels required for the components of the working group processor, capacitors for facilitating stable supply of power to the components, any other components, or a combination thereof.

In certain implementations, the digital frequency locked loop 404 can be utilized to synchronize the frequency of a digital signal (e.g., clock signal or other digital signal) of interest to a desired reference signal. In certain implementations, the clock distribution tree 406 can include a clock source (e.g., crystal oscillator or phase-locked loop) that can generate a clock signal for distribution through the various branches of the clock distribution tree 406. The clock distribution tree 406 can have the clock source serve as the root of the tree and branches (e.g., wiring) from the clock source can be utilized to distribute the clock signal to various components to be synchronized using the clock signal (e.g., components performing operations and/or workloads). In certain implementations, the clock distribution tree 406 can include clock drivers for amplifying and driving the clock signal through the clock distribution tree 406 branches, clock receivers that can receive and synchronize operations with the clock signal, clock gaters that can block the clock signal from traversing certain portions of the clock distribution tree 406, such as to conserve power, along with any other clock distribution tree 406 components.

In certain implementations, the activity counter 408 can be a circuit or component utilized to track capacitive signals traversing the circuitry and wires of the processor. For example, a capacitive activity counter 408 can track such signals for the purposes of monitoring signal integrity and facilitating dynamic power consumption. In certain implementations, the capacitive activity counter 408 can be utilized to monitor transitions such as rising or falling edges of signals, such as signals utilized in digital circuits of processors where capacitors are charged or discharged based on changing logic levels. For example, in certain implementations, the capacitive activity counter 408 can be utilized to count the number of times a signal undergoes a stage change (e.g., transitions from a logical 0 to a logical 1). In certain implementations, the counting by the capacitive activity counter 408 can be utilized to adjust dynamic power consumption, identify abnormal activity occurring in the processor, identify how much power is being consumed by various components of the processor, identify how quickly operations are being processed by the processor, other types of information, or a combination thereof.

In certain scenarios, ringing can occur within the processor (e.g., working group processor), such as when there is a positive feedback loop between the power delivery network 402, the digital frequency locked loop 404, the clock distribution tree 406, and the activity counter 408. For example, the positive feedback loop can occur when a DiDt event occurs (e.g., voltage droop event) in the processor that causes the digital frequency locked loop 404 to stretch and reduce the clock frequency of the clock signal. The stretching and reduction of the clock frequency can then reduce the activity counter 408 (which mitigates voltage droop events), which can then cause the voltage to increase as well. The increase in voltage can cause the frequency to increase (e.g., due to no longer needing the stretch for the clock signal).

In certain implementations, the computing device can disable a feature bit to allow oscillations to be observed within each local processor. With the feature bit enabled, the oscillations can be prevented from being seen, and the activity counter can be reduced when the computing system encounters an unstable state.

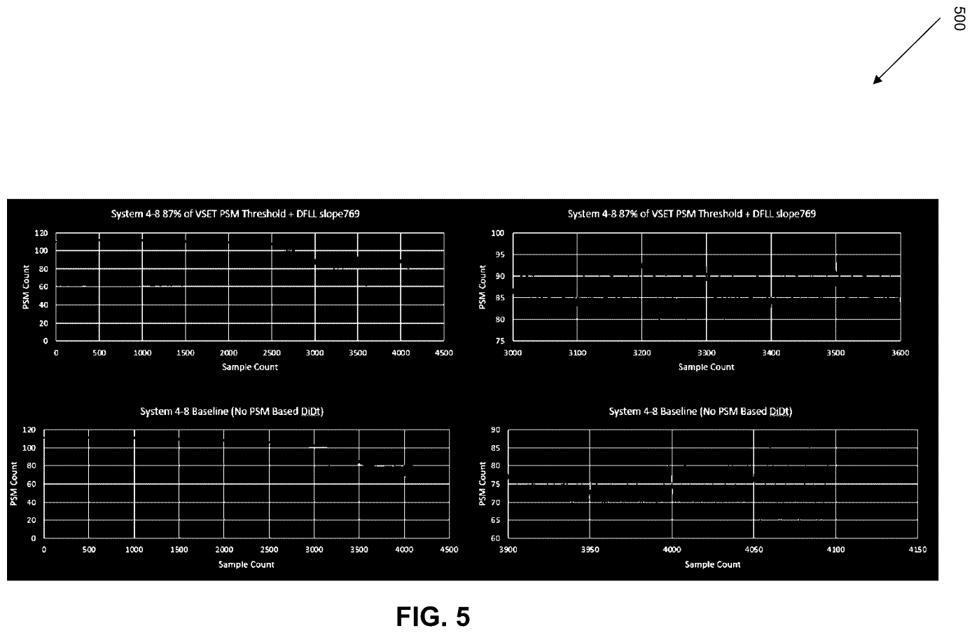

Referring now also to FIG. 5, a schematic diagram providing graphs illustrating performance of the systems according to implementations of the present disclosure in providing ringing mitigation versus performance using traditional techniques. For example, in the top left figure of the schematic diagram 500, the x-axis is the sample count and the y-axis is the power supply monitor count. The graph shows 87% of VSET power supply monitor threshold+DFLL slope of 769. As can be visually seen from the graph, when the DiDt even occurs, the stall pattern is propagated and the system no longer operates in an unstable oscillatory region and there are no system failures caused by ringing. In the top left and right figures of schematic diagram 500, which show use of the functionality provided by the present disclosure, the oscillation and/or fluctuations of the voltage occur in a tight and regulated range. In contrast, without the functionality provided by the present disclosure, the ringing (i.e., voltage oscillations are not controlled and get progressively worse), as shown in the bottom right figure of diagram 500 and the bottom left figure of diagram 500. The bottom right figure of diagram 500 also shows the slope impact using the system and functionality provided by the present disclosure.

FIG. 6 is a flow diagram of an exemplary method 600 for providing ringing mitigation, such as for a semiconductor device. The steps shown in FIG. 6 can be performed by any suitable circuit and/or system, including the system(s), devices, and components illustrated in FIGS. 1, 2, 3, 4 and/or 5. In certain implementations, each of the steps shown in FIG. 6 represent an algorithm whose structure includes and/or is represented by multiple sub-steps, examples of which will be provided in greater detail below. In certain implementations, each of the steps shown in FIG. 6 can represent actions, activities, processes, and/or operations that can be performed by the components of FIGS. 1, 2, 3, 4, and 5. The method 600 can be adapted and/or modified to be utilized with any of the systems, components, and/or devices of FIGS. 1, 2, 3, 4, and 5.

As illustrated in FIG. 6 and in certain implementations, at step 602, the method 600 can include measuring a voltage level associated with a device, such as a semiconductor device. In certain implementations, the voltage level can be measured locally within an individual working group processor (e.g., working group processor 300 or other type of processor) and can be measured by various components of the semiconductor device, such as, but not limited to, a power supply monitor (e.g., power supply monitor 304) of the working group processor. In certain implementations, the method 600 can include, at step 604, comparing the voltage level measured by the power supply monitor to a threshold voltage level. In certain implementations, the threshold voltage level can be a preset static voltage level, however, in certain implementations, the threshold voltage level can be a threshold relative to a moving average of power supply monitor voltage values (or other measurable values, such as current if current is the parameter of choice) measured over a period of time. In certain implementations, the comparing can be conducted by a controller, such as controller 306, which can compare the measured voltage level (or value) to the threshold voltage level (or value).

In certain implementations, the method 600 can proceed to step 606, which can include determining whether the comparing of the voltage level for the working group processor (or other type of processor) is less than the threshold voltage level set for the processor. If, at step 606, the comparing indicates that the voltage level measured by the power supply monitor is at the threshold voltage level or higher, the method 600 can proceed to step 608. In certain implementations, at step 608, the method 600 can include maintaining the current operation of the semiconductor device. The method 600 can then proceed back to step 602 and repeat the steps of the method 600 until the measured voltage level of the working group processor (or other type of processor) is determined to be less than the threshold voltage level based on the comparison. If, however, at step 606, the method 600 includes determining that the measured voltage level associated with the working group processor is less than threshold voltage level set for the working group processor, the method 600 can proceed to step 610.

In certain implementations, at step 610, the method 600 can include determining that a voltage-related event is occurring in the device based on the voltage level being less than the threshold voltage level. In certain implementations, the method 600 can then proceed to step 612. At step 612, the method 600 can include selecting a stall pattern for stalling one or more workloads of the working group processor. In certain implementations, the stall pattern can be selected from a plurality of stall patterns, where each stall pattern can have a different amount of clock cycles over a given period to stall. In certain implementations, the stall patterns can range from a light stall pattern to an aggressive stall pattern, where the light stall patterns stall a fewer number of clock cycles than the aggressive stall patterns. For example, an aggressive stall pattern can stall 14 out of 15 clock cycles or all clock cycles over a period of time, whereas a light clock cycle may stall 2-3 clock cycles out of 15 clock cycles over the period of time. In certain implementations, the stall pattern can be selected based on the severity of the voltage level (e.g., the difference between the measured voltage level and the threshold voltage level is high or beyond a threshold amount), the type of event occurring (e.g., voltage-related event, such as voltage droop or other type of voltage event, current-related event, power related event, etc.), the state of the semiconductor device and/or processor, the duration for which the stall pattern needs to be utilized, any other factor, or a combination thereof.

In certain implementations, the method 600 can then proceed to step 614. At step 614, the method 600 can include injecting the stall pattern into the working group processor (or other device) to stall the workload(s) of the working group device. For example, if the working group processor is processing a variety of operations or is scheduled to perform one or more operations, the stall pattern can be injected by the controller to cause the workload(s) to be stalled. In certain implementations, the method 600 can include maintaining the clock frequency or stretch response by the digital frequency locked loop to prevent reduction of DiDt protection (e.g., protection against voltage droop and/or other types of events). In certain implementations, the method 600 can include causing a reduction in the activity counter of the device to mitigate ringing within the device. In certain implementations, when the stall pattern stalls the workload(s) of the working group processor, the stalling can cause the activity counter to reduce (e.g., reduce in count or reduce the change in count). When the activity counter is reduced and the clock frequency or stretch response is maintained, ringing will be mitigated, while also ensuring protection for the working group processor against DiDt events.

In certain implementations, the method 600 can proceed to step 618. At step 618, the method 600 can include gradually releasing the stall pattern. For example, in certain implementations, the stall pattern can be gradually released by the controller after the voltage-related event ends (e.g., the voltage droop event ends). In certain implementations, the voltage-related event can be determined to have ended if the measured voltage level has increased to satisfy the threshold voltage level. In certain implementations, once the stall pattern is released after performing the gradual release, this will avoid causing new DiDt events that would have resulted from abruptly increasing the activity counter. In certain implementations, the method 600 can then proceed back to step 602 and the method 600 can repeat as desired or as necessary. In certain implementations, the method 600 can incorporate any of the functionality as described in the present disclosure and can be amplified and/or modified accordingly.

Based on at least the foregoing and as detailed herein, the systems and methods provide a mechanism for effective ringing mitigation occurring within a semiconductor device according to implementations of the present disclosure.

As detailed above, the circuits, devices, and systems described and/or illustrated herein broadly represent any type or form of computing device or system capable of executing computer-readable instructions, such as those contained within the modules described herein. In their most basic configuration, these computing device(s) each include at least one memory device and at least one physical processor.

In some examples, the term “memory device” generally refers to any type or form of volatile or non-volatile storage device or medium capable of storing data and/or computer-readable instructions. In one example, a memory device stores, loads, and/or maintains one or more of the modules and/or circuits described herein. Examples of memory devices include, without limitation, Random Access Memory (RAM), Read Only Memory (ROM), flash memory, Hard Disk Drives (HDDs), Solid-State Drives (SSDs), optical disk drives, caches, variations, or combinations of one or more of the same, or any other suitable storage memory.

In some examples, the term “physical processor” generally refers to any type or form of hardware-implemented processing unit capable of interpreting and/or executing computer-readable instructions. In one example, a physical processor accesses and/or modifies one or more modules stored in the above-described memory device. Examples of physical processors include, without limitation, microprocessors, microcontrollers, Central Processing Units (CPUs), Field-Programmable Gate Arrays (FPGAs) that implement softcore processors, Application-Specific Integrated Circuits (ASICs), systems on a chip (SoCs), digital signal processors (DSPs), Neural Network Engines (NNEs), accelerators, graphics processing units (GPUs), portions of one or more of the same, variations or combinations of one or more of the same, or any other suitable physical processor.

In some implementations, the term “computer-readable medium” generally refers to any form of device, carrier, or medium capable of storing or carrying computer-readable instructions. Examples of computer-readable media include, without limitation, transmission-type media, such as carrier waves, and non-transitory-type media, such as magnetic-storage media (e.g., hard disk drives, tape drives, and floppy disks), optical-storage media (e.g., Compact Disks (CDs), Digital Video Disks (DVDs), and BLU-RAY disks), electronic-storage media (e.g., solid-state drives and flash media), and other distribution systems.

The process parameters and sequence of the steps described and/or illustrated herein are given by way of example only and can be varied as desired. For example, while the steps illustrated and/or described herein are shown or discussed in a particular order, these steps do not necessarily need to be performed in the order illustrated or discussed. The various exemplary methods described and/or illustrated herein can also omit one or more of the steps described or illustrated herein or include additional steps in addition to those disclosed.

The preceding description has been provided to enable others skilled in the art to best utilize various aspects of the exemplary implementations disclosed herein. This exemplary description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A system, comprising:
a plurality of working group processors, wherein a first working group processor of the plurality of working group processors comprises:
a controller configured to:
inject, in response to a voltage-related event occurring and while a clock frequency is maintained, a stall pattern locally in the first working group processor to stall a workload of the first working group processor; and
reduce an activity counter based on the stall pattern stalling the workload of the first working group processor.

2. The system of claim 1, wherein the controller is further configured to:
following the reducing of the activity counter, gradually release the stall pattern from a current level until the stall pattern is released.

3. The system of claim 1, wherein the controller is further configured to:
select the stall pattern from a plurality of stall patterns, wherein each stall pattern of the plurality of stall patterns stalls a different amount of clock cycles associated with stalling the workload.

4. The system of claim 1, wherein the controller is further configured to set a threshold voltage level for voltage-related event detection as a preset static threshold voltage level.

5. The system of claim 1, wherein the controller is further configured to:
set a threshold voltage level for voltage-related event detection as a dynamic threshold voltage level, wherein the controller is configured to set the dynamic voltage threshold level relative to a moving average of voltage values measured for the first working group processor over a period of time.

6. The system of claim 1, wherein the controller is further configured to:
monitor, by utilizing a power supply monitor, a voltage level associated with the first working group processor.

7. The system of claim 1, wherein the controller is further configured to:
break a feedback loop occurring among a power delivery network, a digital frequency locked loop, a clock distribution tree, and the activity counter.

8. The system of claim 1, wherein the controller is further configured to:
maintain protection against the voltage-related event, at least one future voltage-related event, a DiDt event, or a combination thereof, by maintaining the clock frequency for the first working group processor.

9. The system of claim 1, wherein the voltage-related event comprises a voltage droop event within the first working group processor.

10. The system of claim 1, wherein the controller is further configured to:
maintain a stretch response slope provided by a digital frequency locked loop to maintain the clock frequency in presence of a feedback loop occurring among a power delivery network, the digital frequency locked loop, a clock distribution tree, and the activity counter of the first working group processor.

11. The system of claim 1, further comprising a second working group processor of the plurality of working group processors, wherein the second working group processor comprises:
a controller configured to:
inject, in response to a different voltage-related event occurring in the second working group processor and while the clock frequency for the second working group processor is maintained, a different stall pattern locally in the second working group processor to stall a different workload of the second working group processor; and
reduce a different activity counter based on the stall pattern stalling the different workload of the second working group processor.

12. A device, comprising:
a controller configured to:
provide, in response to a voltage-related event occurring in the device and while maintaining a clock frequency for the device, a stall pattern locally in the device to stall a workload of the device; and
reduce an activity counter based on the stall pattern stalling the workload of the device.

13. The device of claim 12, wherein the controller is further configured to break a feedback loop occurring among a power delivery network, a digital frequency locked loop, a clock distribution tree, and the activity counter of the device.

14. The device of claim 13, wherein the controller is further configured to:
release, in response to the voltage-related event being over, the stall pattern from a current level until the stall pattern is released.

15. The device of claim 13, wherein the controller is further configured to:
select the stall pattern from a plurality of stall patterns in accordance with a type of the voltage-related event, a severity of the voltage-related event, or a combination thereof.

16. The device of claim 12, wherein the controller is configured to identify the voltage-related event by comparing a voltage level associated with the device to a threshold level.

17. The device of claim 16, wherein the voltage-related event is a voltage droop event.

18. The device of claim 16, wherein the controller is further configured to:
maintain a stretch response slope provided by a digital frequency locked loop to maintain the clock frequency in presence of a feedback loop occurring among a power delivery network, the digital frequency locked loop, a clock distribution tree, and the activity counter of the device.

19. A method, comprising:
providing, in response to a voltage-related event occurring in a device and while maintaining a clock frequency for the device, a stall pattern locally in the device to stall a workload of the device; and
reducing an activity counter based on the stall pattern stalling the workload of the device to mitigate ringing within the device.

20. The method of claim 19, further comprising gradually releasing the stall pattern after the voltage-related event ends and a voltage level satisfies a threshold voltage level.
